(19) United States
(12) Patent Application Publication
(10) Pub. No.: US 2017/0229282 A1
(43) Pub. Date: Aug. 10, 2017

(54) METHOD FOR EVALUATING SHAPING APERTURE ARRAY

(71) Applicant: NuFlare Technology, Inc., Yokohama-shi (JP)

(72) Inventor: Satoru HIROSE, Yokohama-shi (JP)

(73) Assignee: NuFlare Technology, Inc., Yokohama-shi (JP)

(21) Appl. No.: 15/421,740

(22) Filed: Feb. 1, 2017

(30) Foreign Application Priority Data
Feb. 10, 2016 (JP) 2016-023756

(51) Int. Cl. H01J 37/22; H01J 37/244; H01J 37/28

(52) U.S. Cl. CPC H01J 37/222; H01J 37/28; H01J 37/244; H01J 2237/24578; H01J 2237/2817

(57) ABSTRACT

In one embodiment, a method for evaluating a shaping aperture array includes forming a plurality of evaluation patterns on a substrate, the evaluation patterns each including a first line portion along a first direction and a second line portion along a second direction perpendicular to the first direction by performing writing using a plurality of beams formed by passage of a charged particle beam through a shaping aperture array having a plurality of holes, measuring, for each of the plurality of evaluation patterns, a position of the first line portion in the second direction, a position of the second line portion in the first direction, and a line width of the first line portion or the second line portion, and evaluating accuracy of the plurality of holes based on a result of measurement. Each evaluation pattern is written using one beam that has passed through a corresponding one of the holes in the shaping aperture array.

### CROSS REFERENCE TO RELATED APPLICATION

This application is based upon and claims benefit of priority from the Japanese Patent Application No. 2016-023756, filed on Feb. 10, 2016, the entire contents of which are incorporated herein by reference.

### FIELD

The present invention relates to a method for evaluating shaping aperture array.

### BACKGROUND

Along with an improvement in integration of LSIs, circuit line widths of semiconductor devices have become finer. As an example of a method for forming exposure masks (exposure masks used in steppers and scanners are also called reticles) that are used for forming circuit patterns in such semiconductor devices, an electron-beam writing technology having high resolution has been used.

For example, there is a writing apparatus using multibeams. Numerous beams can be radiated at a time (at one shot) by using multibeams, and thus, an improvement in throughput can be achieved compared with the case of performing writing by using one electron beam. In a multi-beam writing apparatus, for example, multibeams are formed by causing an electron beam emitted from an electron gun to pass through a shaping aperture array having a plurality of holes, and blanking control of each of the beams is performed by a blanking plate. The beams that are not blocked are radiated onto desired locations on a sample.

Depending on the processing accuracy of the shaping aperture array, the positions and sizes of the holes vary to reduce the writing accuracy. Thus, evaluating deviations in position and size of the individual holes from design values and producing a correction map for correcting the deviations from the design values. However, separately writing a pattern for evaluating deviations in position and a pattern for evaluating deviations in size has a problem in that it takes much time to evaluate the shaping aperture array.

### BRIEF DESCRIPTION OF THE DRAWINGS

FIG. 1 is a schematic diagram of a writing apparatus according to an embodiment of the present invention.

FIG. 2 is a plan view of a shaping aperture array.

FIG. 3 is a flowchart illustrating a method for evaluating the shaping aperture array according to the embodiment.

FIG. 4A is a diagram illustrating an example of the shaping aperture array, and FIG. 4B is a diagram illustrating a multibeams irradiation area.

FIG. 5 is a diagram illustrating an example of an evaluation pattern.

FIGS. 6A to 6C are diagram illustrating examples of measurement of an evaluation pattern.

FIG. 7 is a diagram illustrating an evaluation pattern according to a comparative example.

FIG. 8 is a diagram illustrating an example of an evaluation pattern.

FIG. 9 is a diagram illustrating an example of an evaluation pattern.

FIG. 10 is a diagram illustrating an example of an evaluation pattern.

FIG. 11 is a diagram illustrating an example of the configuration of a region of interest (ROI) of a line pattern.

FIG. 12 is a diagram illustrating an example of area division of a shaping aperture array.

### DETAILED DESCRIPTION

In one embodiment, a method for evaluating a shaping aperture array includes forming a plurality of evaluation patterns on a substrate, the evaluation patterns each including a first line portion along a first direction and a second line portion along a second direction perpendicular to the first direction by performing writing using a plurality of beams formed by passage of a charged particle beam through a shaping aperture array having a plurality of holes, measuring, for each of the plurality of evaluation patterns, a position of the first line portion in the second direction, a position of the second line portion in the first direction, and a line width of the first line portion or the second line portion, and evaluating accuracy of the plurality of holes based on a result of measurement. Each evaluation pattern is written using one beam that has passed through a corresponding one of the holes in the shaping aperture array.

An embodiment of the present invention will be described below with reference to the drawings.

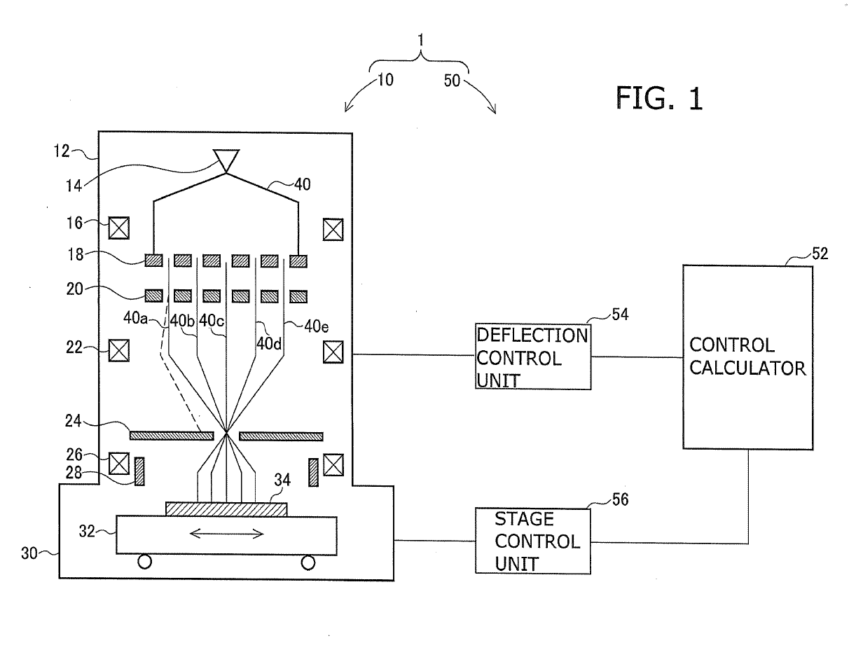

FIG. 1 is a schematic diagram of a writing apparatus according to an embodiment of the present invention. A writing apparatus 1 shown in FIG. 1 is a multi-charged-particle-beam writing apparatus including a writing unit 10 that applies an electron beam onto an object, such as a mask or a wafer, to write a desired pattern and a control unit 50 that controls the operation of the writing unit 10.

The writing unit 10 includes an electron-beam lens barrel 12 and a writing chamber 30. The electron-beam lens barrel 12 contains an electron gun 14, an illumination lens 16, a shaping aperture array 18, a blanking plate 20, a reducing lens 22, a limiting aperture member 24, an objective lens 26, and a deflector 28.

The writing chamber 30 contains an X-Y stage 32. A substrate 34, which is an object of writing, is placed on the X-Y stage 32. Examples of the object substrate include a wafer and a photomask for transferring a pattern to a wafer using a reduced-projection exposure unit using an excimer laser as a light source, such as a stepper or a scanner, or an extreme ultraviolet exposure unit. Another example of the object substrate is a mask on which a pattern has already been formed. For example, a Levenson-type mask needs two times of writing operation, and therefore the second pattern is formed on a mask processed by writing.

The control unit 50 includes a control calculator 52, a deflection control unit 54, and a stage control unit 56. At least part of the control calculator 52, the deflection control unit 54, and the stage control unit 56 may be composed of either hardware or software. With software, a program for implementing at least part of the functions may be stored in a recording medium, such as a flexible disk or CD-ROM, and the program may be read by a computer including an electric circuit for execution. The recording medium is not limited to detachable recording media, such as a magnetic disk and an optical disk, but may be a fixed-type recording medium, such as a hard disk or a memory.

In the electron-beam lens barrel 12, an electron beam 40 emitted from the electron gun 14 substantially vertically illuminates the whole of the shaping aperture array 18 for forming multibeams through the illumination lens 16.

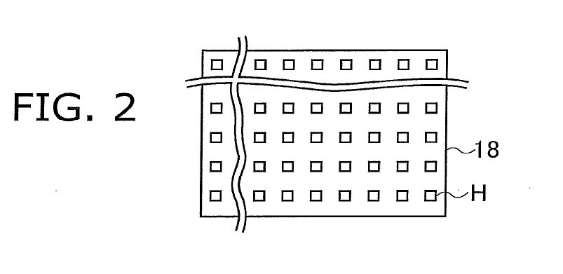

FIG. 2 is a plan view of the shaping aperture array 18. As shown in FIG. 2, the shaping aperture array 18 has a plurality of arrays of holes H in the vertical direction (Y-direction) and the lateral direction (X-direction) at a predetermined pitch in a matrix form. The holes H each have a rectangular shape with the same design size. The electron beam 40 passes through the plurality of holes H to form multibeams 40a to 40e shown in FIG. 1.

The blanking plate 20 has through holes according to the positions of the holes H of the shaping aperture array 18. Each through hole is provided with a blanker including a pair of electrodes. The electron beams 40a to 40e passing through the through holes are independently deflected by voltages applied to the blankers. Thus, the plurality of blankers perform blanking deflection of corresponding beams of the multibeams that have passed through the plurality of holes H of the shaping aperture array 18.

The multibeams 40a to 40e that have passed through the blanking plate 20 are reduced by the reducing lens 22 and move toward a central hole formed in the limiting aperture member 24. The electron beams deflected by the blankers of the blanking plate 20 deviate in position from the central hole in the limiting aperture member 24 and are blocked by the limiting aperture member 24. In contrast, electron beams that have not been deflected by the blankers of the blanking plate 20 pass through the central hole in the limiting aperture member 24.

The limiting aperture member 24 blocks the beams that are deflected by the blankers of the blanking plate 20 into beam OFF. Beams that have passed through the limiting aperture member 24 from beam ON until beam OFF are one shot of beams. The multibeams 40a to 40e that have passed through the limiting aperture member 24 are focused by the objective lens 26 to form a pattern image with a desired reduction rate. The beams (the whole multibeams) that have passed through the limiting aperture member 24 are collectedly deflected in the same direction by the deflector 28 onto a desired irradiation position on the substrate 34.

While the X-Y stage 32 is continuously moving, the beam irradiation position is controlled by the deflector 28 to follow the movement of the X-Y stage 32. The X-Y stage 32 is moved according to the stage control unit 56.

The control calculator 52 performs a plurality of steps of data conversion processing on writing data to generate shot data specific to the apparatus. The shot data includes the amount of irradiation and the coordinates of an irradiation position at each shot.

The control calculator 52 outputs the amount of irradiation at each shot to the deflection control unit 54 on the basis of the shot data. The deflection control unit 54 divides the input amount of irradiation by a current density to obtain irradiation time t. In performing a corresponding shot, the deflection control unit 54 applies deflection voltages to corresponding blankers of the blanking plate 20 so that the blankers turn ON for the irradiation time t.

The control calculator 52 outputs deflected-position data to the deflection control unit 54 so that the individual beams are deflected to positions (coordinates) indicated by the shot data. The deflection control unit 54 calculates the amount of deflection and applies a deflection voltage to the deflector 28. Thus, the multibeams emitted at the shot are collectively deflected.

If the positions and sizes of the plurality of holes H in the shaping aperture array 18 vary in the writing apparatus 1, it is necessary to evaluate the deviations in the positions and sizes of the individual holes H from design values and to prepare a correction map for correcting the deviations from the design values. A method for evaluating the deviations in the positions and sizes of the holes H will be described herein below.

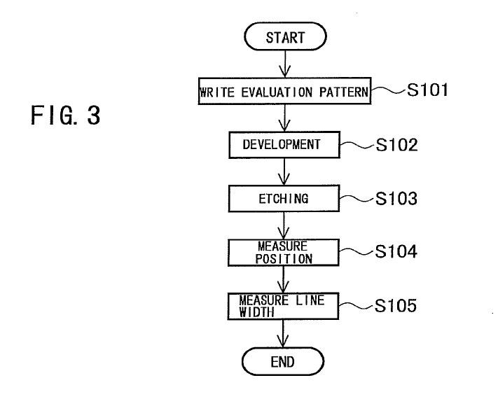

FIG. 3 is a flowchart illustrating a method for evaluating the plurality of holes H formed in the shaping aperture array 18. As shown in FIG. 3, this method includes a process for writing an evaluation pattern on a resist film on the substrate (step S101), a process for performing a developing process to form a resist pattern (step S102), a process for performing etching using the resist pattern as a mask to form an evaluation pattern on a light shielding layer (step S103), a process for measuring the position of the evaluation pattern (step S104), and a process for measuring the line width of the evaluation pattern (step S105).

At step S101, multibeams are applied to the substrate 34 for evaluation placed on the X-Y stage 32 to draw an evaluation pattern. An example of the evaluation substrate 34 is a glass substrate on which a light shielding layer, such as a chromium film, and a resist film are layered.

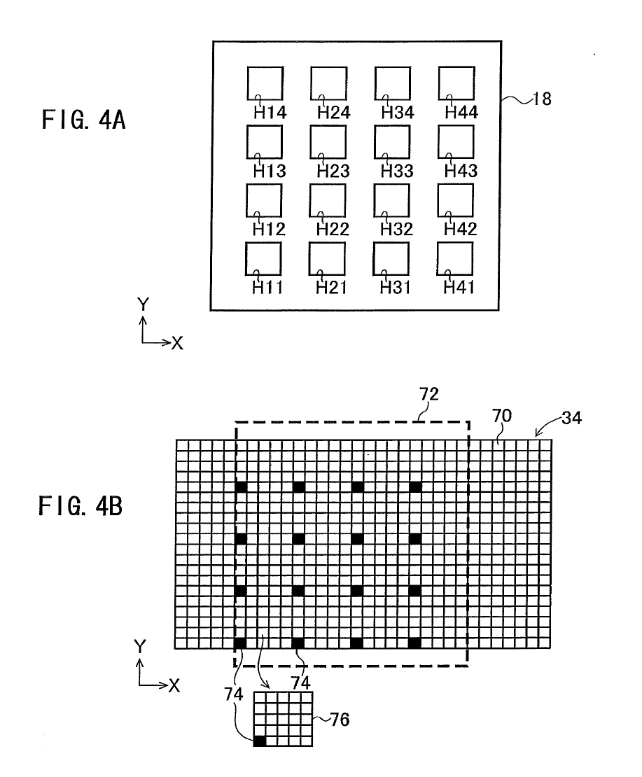

FIG. 4A illustrates an example of the shaping aperture array 18 including 16 holes H11 to H14, H21 to H24, H31 to H34, and H41 to H44 in 4- by 4-matrix. FIG. 4B illustrates an example of a multibeam irradiation area formed by the shaping aperture array 18 shown in FIG. 4A and object pixels.

As shown in FIG. 4B, the evaluation pattern writing area of the substrate 34 is divided into mesh regions, and each mesh region serves as an object pixel 70 (drawn position). A plurality of (16 in this embodiment) pixels 74 that can be irradiated by one multibeam irradiation are illustrated in an irradiation area 72 that can be irradiated by one multibeam irradiation. The pitch between adjacent pixels 74 is the pitch of the multibeam.

In the example in FIG. 4B, a square region with a length of the beam pitch on one side in the X-direction and Y-direction constitutes one grid 76. In the example of FIG. 4B, each grid 76 is composed of 5×5 pixels.

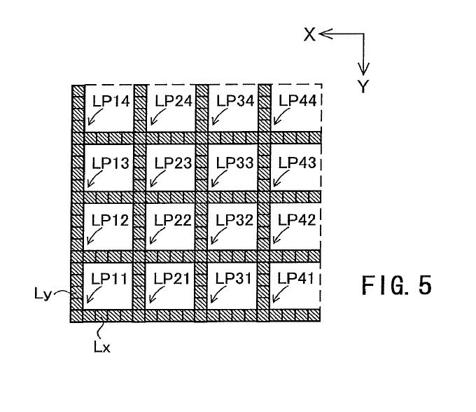

As shown in FIG. 5, five pixels arrayed in the X-direction and five pixels arrayed in the Y-direction in each grid 76 are exposed to light to draw L-shape patterns LP11 to LP14, LP21 to LP24, LP31 to LP34, and LP41 to LP44 each including a line portion Lx along the X-direction and a line portion Ly along the Y-direction. An L-shape pattern LPmn (m and n are respectively integers that satisfy 1≦m, n≦4) is drawn using a beam that has passed through a hole Hmn of the shaping aperture array 18. For example, the L-shape pattern LP11 is drawn using a beam that has passed through the hole H11 in the shaping aperture array 18 shown in FIG. 4A.

There is one beam crossover point between the shaping aperture array 18 and the substrate 34. For that reason, the array of the L-shape patterns LPmn is symmetrical about the X-axis and the Y-axis to the array of the holes Hmn of the shaping aperture array 18. In FIG. 5, the X-Y coordinate system is rotated 180 degrees so that the array of the L-shape patterns LPmn are apparently aligned with the array of the holes Hmn in FIG. 4A.

In writing the L-shape patterns LPmn, the multibeam irradiation position may be moved either by deflection by the deflector 28 or by movement of the X-Y stage 32.

After the L-shape patterns LPmn are drawn, the resist film irradiated with the electron beams is developed using a known developing unit and a developer (step S102). A portion of the resist film irradiated with the electron beams is solubilized against the developer to form a resist pattern.

Subsequently, the light shielding layer whose surface is exposed is etched using the resist pattern as a mask (step S103). Thus, the light shielding layer is processed to form L-shape evaluation patterns. After the etching, the resist pattern is removed by, for example, ashing.

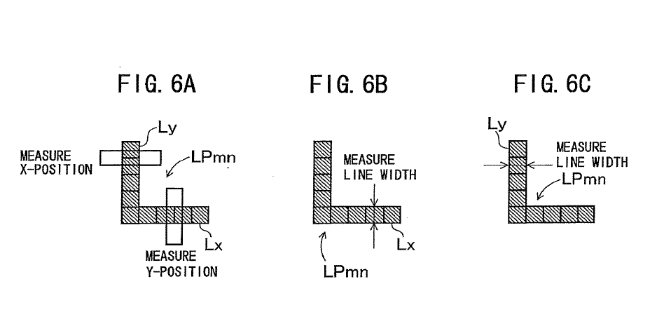

The positions and line widths of the evaluation patterns are measured using a measuring device, such as a critical dimension-scanning electron microscope (CD-SEM) (steps S104 and S105). For example, as shown in FIG. 6A, the position of a line portion Lx of the L-shape pattern LPmn in the Y-direction (y-position) and the position of a line portion Ly in the X-direction (x-position) are measured. From the measured x-position and y-position, deviations in the x-position and y-position of the hole Hmn in the shaping aperture array 18 which forms a beam used in writing the evaluation pattern LPmn from the design values can be evaluated.

Furthermore, as shown in FIG. 6B or FIG. 6C, the line width of the line portion Lx or Ly is measured. From the measured line width, deviations of the size of the hole Hmn in the shaping aperture array 18 which forms the beam used in writing the L-shape pattern LPmn from the design value can be evaluated. Alternatively, the line widths of both of the line portion Lx and the line portion Ly may be measured, and an average value thereof may be obtained.

Measuring the y-positions of the line portions Lx, the x-positions of the line portions Ly, and the line widths thereof of all of the L-shape patterns LP11 to LP14, LP21 to LP24, LP31 to LP34, and LP41 to LP44 allows deviations of the x-positions, y-positions, and sizes of the holes H11 to H14, H21 to H24, H31 to H34, and H41 to H44 of the shaping aperture array 18 from design values to be obtained, and the accuracy (processing accuracy) of the individual holes H to be evaluated from the deviations (differences) from the design values. Furthermore, a correction map for correcting the deviations from the design values can be created on the basis of the evaluation result. In writing an actual pattern using the writing apparatus 1, the writing position and the beam irradiation amount can be corrected on the basis of the correction map, so that variations in the positions and sizes of the holes H of the shaping aperture array 18 can be corrected, and thus the writing accuracy can be improved.

Measuring the positions and the line widths of the line portions Lx and Ly of the L-shape patterns LPmn allows the x-positions, the y-positions, and the sizes of the holes Hmn of the shaping aperture array 18 to be evaluated. This embodiment does not need to separately draw a pattern for evaluating a position gap and a pattern for evaluating a size gap, allowing efficient evaluation of the shaping aperture array 18.

### Comparative Example

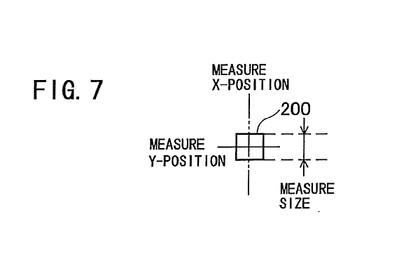

Consider a case in which only one pixel is irradiated with a beam to form an evaluation pattern 200, and the position and size of the evaluation pattern 200 is measured, as shown in FIG. 7.

With this evaluation pattern 200, if the position (the center of gravity) is deviated from a design value, it is difficult to determine whether the position of the hole H of the shaping aperture array 18 is deviated from a design value or the size of the hole H is deviated from a design value.

In contrast, the above embodiment applies beams to a plurality of pixels in each of the x-direction and the y-direction to form an L-shape evaluation pattern including a line portion extending in the x-direction and a line portion extending in the y-direction. The x-position and the y-position of the hole H are evaluated from the measurement results of the position of the individual line portions, and the size of the hole H is evaluated from the measurement results of the line widths of the line portions. This allows accurate evaluation of deviations in the position and size of the hole H.

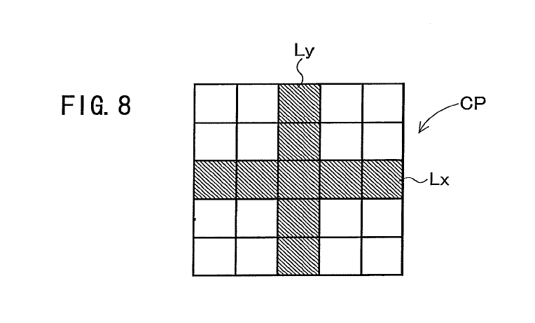

The above embodiment illustrates an example in which the L-shape pattern LP in which one end of the line portion Lx along the X-direction and one end of the line portion Ly along the Y-direction overlap one another is drawn as an evaluation pattern. Alternatively, portions other than the ends may be overlapped. For example, a cross-shape pattern CP in which the line portion Lx and the line portion Ly cross each other, as shown in FIG. 8, may be used.

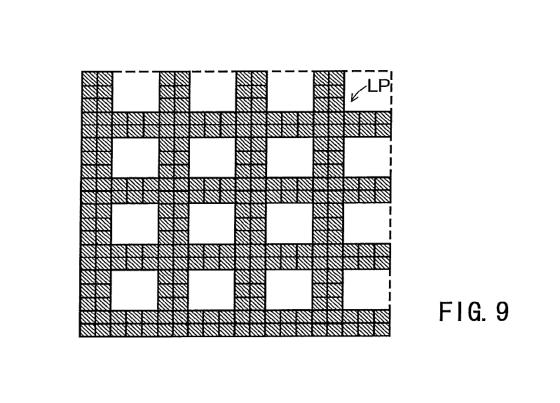

The above embodiment illustrates an example in which pixels arrayed in a line in each of the X-direction and the Y-direction are exposed to light to draw the L-shape pattern LP. Alternatively, if the size (beam size) per pixel is small and so makes the line portions thin, making it difficult to measure the line portions using a measuring device, a plurality of arrays of pixels in each of the X-direction and Y-direction may be exposed to light to form an L-shape pattern. FIG. 9 illustrates an example in which two arrays of pixels are exposed to light to form an L-shape pattern. Including a plurality of pixel arrays makes the line widths of the line portions thick, facilitating measurement using a measuring device.

The above embodiment illustrates an example in which one L-shape pattern LP is drawn in one grid 76, and L-shape patterns drawn using beams that have passed through adjacent holes H are located next to each other also on the substrate. Alternatively, if the beam pitch is so small that the line portions of the L-shape pattern LP cannot have sufficient lengths, one L-shape pattern may be drawn in a plurality of grids 76. Writing such L-shape patterns is preferable in a case where it is difficult to ensure sufficient lengths of line portions because a plurality of arrays of pixels in each of the X-direction and the Y-direction are exposed to light to make the line widths of the line portions thick (see FIG. 9).

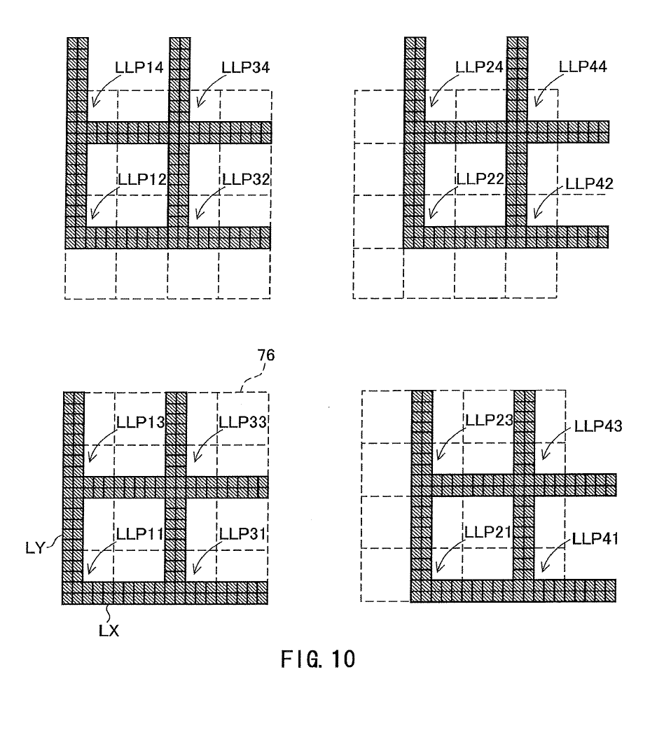

FIG. 10 illustrates an example in which ten pixels arrayed in two rows in each of the X-direction and the Y-direction are exposed to light to draw an L-shape pattern LLP including a line portion LX along the X-direction and a line portion LY along the Y-direction. The line portions LX and LY are each drawn across two grids 76.

In this case, the beams are alternately subjected to blanking to draw four L-shape patterns LLP. The blanking beams are changed to draw four L-shape patterns LLP four times. For example, first, four L-shape patterns LLP11, LLP31, LLP13, LLP33 are drawn using beams that have passed through the holes H11, H31, H13, and H33 of the shaping aperture array 18 shown in FIG. 4A. The L-shape pattern LLP11 drawn using a beam that has passed through the hole H11 and the L-shape pattern LLP31 drawn using a beam that has passed through the hole H31 located with the hole H21 between it and the hole H11 are located next to each other on the substrate.

Next, four L-shape patterns LLP21, LLP41, LLP23, and LLP43 are drawn using beams that have passed through the holes H21, H41, H23, and H43 of the shaping aperture array 18. Subsequently, four L-shape patterns LLP12, LLP32, LLP14, and LLP34 are drawn using beams that have passed through the holes H12, H32, H14, and H34 of the shaping aperture array 18. Subsequently, four L-shape patterns LLP22, LLP42, LLP24, and LLP44 are drawn using beams that have passed through the holes H22, H42, H24, and H44 of the shaping aperture array 18.

Thus, increasing the lengths and line widths of L-shape patterns makes measurement of the positions and line widths easy.

The above embodiment illustrates an example in which 16 holes H in 4- by 4-matrix are provided in the shaping aperture array 18. In some embodiments, the shaping aperture array 18 is provided with many holes H in 512- by 512-matrix. In this case, 512×512 L-shape patterns LP are drawn, and the positions and the line widths of the line portions Lx and Ly of the L-shape patterns LP are measured.

If the shaping aperture array 18 has many holes H, the number of L-shape patterns of which the positions and the line widths of the line portions Lx and Ly are to be measured may be reduced to reduce the time required for evaluation. For example, the holes H are grouped into a plurality of groups, and preparatory evaluation patterns are drawn using beams that have passed through the holes H of the groups in addition to the L-shape patterns LP. A group to be measured is selected from the result of measurement of the preparatory evaluation patterns, and the positions and line widths of the line portions Lx and Ly are measured only on L-shape patterns LP drawn using beams that have passed through the holes H of the selected group.

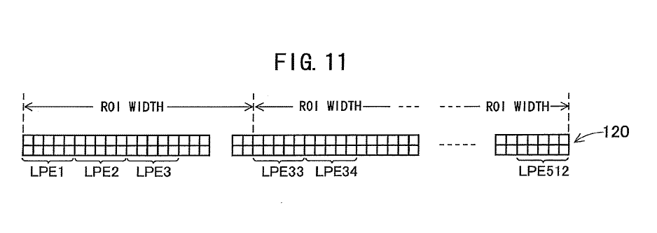

For example, beams that have passed through the holes H are applied in the X-direction by an amount corresponding to the beam pitch to draw line patterns serving as preparatory evaluation patterns. FIG. 11 illustrates a line pattern (a preparatory evaluation pattern) 120 that is drawn using beams that have passed through holes H (1,1) to H (512,1) arrayed in the X-direction in the shaping aperture array 18. The line pattern 120 is a contiguous sequence of a line pattern element LPE1 drawn using a beam that has passed through the hole H (1,1), a line pattern element LPE2 drawn using a beam that has passed through the hole H (2,1), . . . , and a line pattern element LPE512 drawn using a beam that has passed through the hole H (512, 1).

The width of a region-of-interest (ROI) in a scanning electron microscopic (SEM) image of the line pattern 120 is taken as a plurality of continuous line pattern elements. The line edge roughness (LER) of the line composed of a plurality of line pattern elements is measured. If the LER is greater than a predetermined value, an L-shape pattern drawn using corresponding beams is selected as the object to be measured.

For example, the holes H (1,1) to H (32,1) of the shaping aperture array 18 are grouped, and a line composed of line pattern elements LPE1 to LPE32 is set as a ROI, and the LER of the ROI is obtained. If the LER is greater than a predetermined value, the group of the holes H (1,1) to H (32,1) is measured, that is, an L-shape pattern drawn using beams that have passed through the holes is measured. In contrast, if the LER is equal to or less than the predetermined value, the group of THE holes H (1,1) to H (32,1) is not measured, that is, the L-shape pattern drawn using the beams that have passed through the holds is not measured.

This reduces the number of L-shape patterns for measuring the positions and line widths of the line portions Lx and Ly, thereby reducing the time required for evaluation.

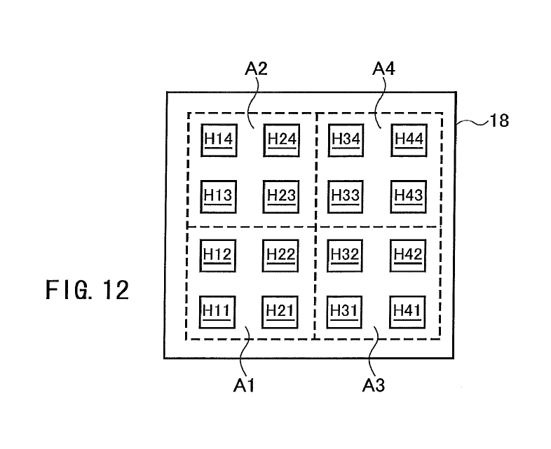

The method for selecting L-shape patterns for measuring the positions and line widths of the line portions Lx and Ly is given for mere illustration. For example, a method disclosed in Japanese Patent Application (Japanese Patent Application No. 2015-230771) applied by the applicant may be employed. With this method, first the shaping aperture array 18 is divided into a plurality of areas to group the holes H. For example, as shown in FIG. 12, the shaping aperture array 18 is divided into an area A1 including the holes H11, H21, H12, and H22, an area A2 including holes H13, H23, H14, and H24, an area A3 including holes H31, H41, H32, and H42, and an area A4 including holes H33, H43, H34, and H44.

Then, four L-shape patterns are drawn using beams that have passed through the holes H11, H21, H12, and H22 of the area A1, and four times of writing is performed, with the writing position shifted in the X-direction and the Y-direction to draw preparatory evaluation patterns including 16 L-shape patterns arrayed as in FIG. 5.

Subsequently, four L-shape patterns are drawn four times using beams that have passed through the holes H13, H23, H14, and H24 of the area A2 to draw 16 L-shape patterns (preparatory evaluation patterns). Likewise, four L-shape patterns are drawn four times using beams that have passed through the holes H31, H41, H32, H42 of the area A3 to draw 16 L-shape patterns (preparatory evaluation patterns). Furthermore, four L-shape patterns are drawn four times using beams that have passed through the holes H33, H43, H34, and H44 in the area A4 to draw 16 L-shape patterns (preparatory evaluation patterns).

Next, the 16 L-shape patterns drawn using the beams that have passed through the holes H11, H21, H12, and H22 in the area A1 and the 16 L-shape patterns shown in FIG. 5 are compared to obtain a difference in each of the areas A1 to A4. An example of the difference is the sum of areas that appear in a difference image in a SEM image.

Likewise, the 16 L-shape patterns drawn using the beams that have passed through the holes H13, H23, H14, and H24 in the area A2 and the 16 L-shape patterns shown in FIG. 5 are compared to obtain a difference in each of the areas A1 to A4.

Likewise, the 16 L-shape patterns drawn using the beams that have passed through the holes H31, H41, H32, and H42 in the area A3 and the 16 L-shape patterns shown in FIG. 5 are compared to obtain a difference in each of the areas A1 to A4.

Likewise, the 16 L-shape patterns drawn using the beams that have passed through the holes H33, H43, H34, and H44 in the area A4 and the 16 L-shape patterns shown in FIG. 5 are compared to obtain a difference in each of the areas Al to A4.

In the four times of comparative evaluation, the differences in the areas A1 to A4 including holes H that significantly deviate from design values are often equal to or greater than a predetermined value. For that reason, L-shape patterns drawn using beams that have passed through holes H in an area in which the difference is equal to or greater than a predetermined value many times is selected as the object to be measured. This reduces the number of L-shape patterns for measuring the positions and line widths of the line portions Lx and Ly, further reducing the time required for evaluation.

While the above embodiment illustrates a configuration in which electron beams are applied, other charged particle beams, such as ion beams, may be applied.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method for evaluating a shaping aperture array comprising:
forming a plurality of evaluation patterns on a substrate, the evaluation patterns each including a first line portion along a first direction and a second line portion along a second direction perpendicular to the first direction by performing writing using a plurality of beams formed by passage of a charged particle beam through a shaping aperture array having a plurality of holes;
measuring, for each of the plurality of evaluation patterns, a position of the first line portion in the second direction, a position of the second line portion in the first direction, and a line width of the first line portion or the second line portion; and
evaluating accuracy of the plurality of holes based on a result of measurement,
wherein each evaluation pattern is written using one beam that has passed through a corresponding one of the holes in the shaping aperture array.

2. The method according to claim 1, wherein a first evaluation pattern written using a first beam that has passed through a first hole of the shaping aperture array and a second evaluation pattern written using a second beam that has passed through a second hole next to the first hole are located next to each other on the substrate.

3. The method according to claim 1, wherein a first evaluation pattern written using a first beam that has passed through a first hole of the shaping aperture array and a third evaluation pattern written using a third beam that has passed through a third hole located, with at least one hole sandwiched between the third hole and the first hole, are located next to each other on the substrate.

4. The method according to claim 1,
wherein the first line portion includes a plurality of pixel arrays extending in the first direction, and
wherein the second line portion includes a plurality of pixel arrays extending in the second direction.

5. The method according to claim 1,
wherein an preparatory evaluation pattern is written using the plurality of beams,
wherein the holes in the shaping aperture array are grouped into a plurality of groups,
wherein a group to be measured is selected based on a result of evaluation of the preparatory evaluation pattern, and
wherein the positions and the line width are measured for an evaluation pattern written using beams that have passed through holes in the group to be measure.

6. The method according to claim 5,
wherein the preparatory evaluation pattern is a line pattern including a contiguous sequence of line pattern elements written using beams that have passed through holes next to each other in the first direction,
wherein the line pattern is divided into a plurality of areas, and line edge roughness (LER) in each area is measured, and
wherein a plurality of holes corresponding to an area in which the LER is greater than a predetermined value are selected as the group to be measured.

7. The method according to claim 1, wherein a first line width of the first line portion and a second line width of the second line portion are measured, and an average value of the first line width and the second line width is used in evaluating accuracy of the plurality of holes.

8. The method according to claim 1, wherein the evaluation pattern has an L shape in which one end of the first line portion and one end of the second line portion overlap with one another.

9. The method according to claim 1, wherein the evaluation pattern has a cross shape in which the first line portion and the second line portion cross each other.
